(19) United States
(12) Patent Application Publication
(10) Pub. No.: US 2025/0344385 A1
(43) Pub. Date: Nov. 6, 2025

(54) MEMORY DEVICE AND METHOD OF MANUFACTURING THE SAME

(71) Applicant: Winbond Electronics Corp., Taichung City (TW)

(72) Inventors: Chia-Jung CHUANG, Taichung City (TW); Cheng-Chiang LI, Taichung City (TW); Kao-Chun CHEN, Taichung City (TW)

(73) Assignee: Winbond Electronics Corp., Taichung City (TW)

(21) Appl. No.: 19/195,921

(22) Filed: May 1, 2025

(30) Foreign Application Priority Data
May 6, 2024 (TW) 113116670

(51) Int. Cl. H10B 41/40; H10B 41/10; H10B 41/20; H10B 43/10; H10B 43/20; H10B 43/40

(52) U.S. Cl. CPC H10B 41/40; H10B 41/10; H10B 41/20; H10B 43/10; H10B 43/20; H10B 43/40

(57) ABSTRACT

A method of manufacturing a memory device is provided, including providing a substrate with an array region and a peripheral region. The method includes forming a stacked layer on the substrate, forming a hard mask layer on the stacked layer, and performing a first patterning process on the substrate to form an array pattern in the array region. The first patterning process further forms a connecting pattern in the peripheral region. The method further includes performing a second patterning process on the peripheral region of the substrate to sequentially form a first pattern and a second pattern over the connecting pattern, and performing an etching process on the substrate to sequentially transfer the connecting pattern, the first pattern, and the second pattern to the hard mask layer and the stacked layer to form a peripheral circuit in the peripheral region.

### CROSS REFERENCE TO RELATED APPLICATIONS

This application claims priority of Taiwan Patent Application No. 113116670 filed on May 6, 2024, the entirety of which is incorporated by reference herein.

### BACKGROUND

### Technical Field

The present disclosure relates to semiconductor technology, and in particular it relates to a memory device and a method of manufacturing the same.

### Description of the Related Art

As the resolution of conventional photolithography processes gradually approaches the theoretical limit, manufacturers have begun to turn to methods such as double-patterning (DP) to overcome optical limits and further improve the integration density of memory components.

Due to the scaling down of the photolithography process for forming peripheral circuits in the patterning methods used for memory devices, multiple photolithography processes may currently be applied to the formation of peripheral circuits. However, the overlapping of these patterns may cause damage to the final structure during the subsequent etching process, potentially leading to unnecessary impacts on the proper operation of memory device and causing electrical issues. Therefore, the industry still needs to improve the methods of manufacturing memory devices to achieve its goal of maintaining the yield of memory devices.

### BRIEF SUMMARY

The present disclosure provides a method of manufacturing a memory device, including providing a substrate with an array region and a peripheral region, forming a stacked layer on the substrate, and forming a hard mask layer on the stacked layer. The method further includes performing a first patterning process on the substrate to form an array pattern in the array region, wherein the first patterning process forms a connecting pattern in the peripheral region. The method further includes performing a second patterning process on the peripheral region of the substrate to sequentially form a first pattern and a second pattern over the connecting pattern. The method further includes performing an etching process on the substrate to sequentially transfer the connecting pattern, the first pattern, and the second pattern to the hard mask layer and the stacked layer to form a peripheral circuit in the peripheral region.

In a top view, one end of the connecting pattern overlaps the first pattern, and the other end of the connecting pattern overlaps the second pattern, in the top view, the first pattern is connected to the second pattern by the connecting pattern, the overlapping area of the connecting pattern and the first pattern is equal to the overlapping area of the connecting pattern and the second pattern, the connecting pattern includes a corner, the angle of the corner is not greater than 90 degrees.

The first pattern and the second pattern are parallel to each other, the first patterning process includes a self-aligned double patterning (SADP) process, the array pattern and the connecting pattern are formed simultaneously, before forming the hard mask layer on the stacked layer, further including forming a sacrificial layer on the stacked layer, the sacrificial layer protects the stacked layer from etching during the transfer of the connecting pattern, the first pattern, and the second pattern to the hard mask layer, the hard mask layer includes polysilicon, and the sacrificial layer includes silicon oxide.

The present disclosure provides a memory device, including a substrate with an array region and a peripheral region, and a peripheral circuit in the peripheral region. The peripheral circuit includes a first portion and a second portion, and the first portion and the second portion are electrically connected by a connecting portion.

The connecting pattern includes a corner, the angle of the corner is not greater than 90 degrees, the connecting portion has a width in a first direction, and the width is greater than the distance between the first portion and the second portion in the first direction, the first portion is arranged in a first direction and extends in a second direction, and the second portion is arranged in the first direction and extends in the second direction, the connecting portion includes a rectangle, an L-shape, or a combination thereof. The contact area of the first portion with the connecting portion is equal to the contact area of the second portion with the connecting portion, the first portion and the second portion are parallel to each other, the connecting portion is in contact with one end of the first portion.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1, 2, 5A, 5B, and 5C illustrate perspective views of intermediate stages of manufacturing the memory device according to the embodiments of the present disclosure.

FIGS. 3A, 3B, 3C, and 4 illustrate top views of intermediate stages of manufacturing the memory device according to the embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first feature and the second feature are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

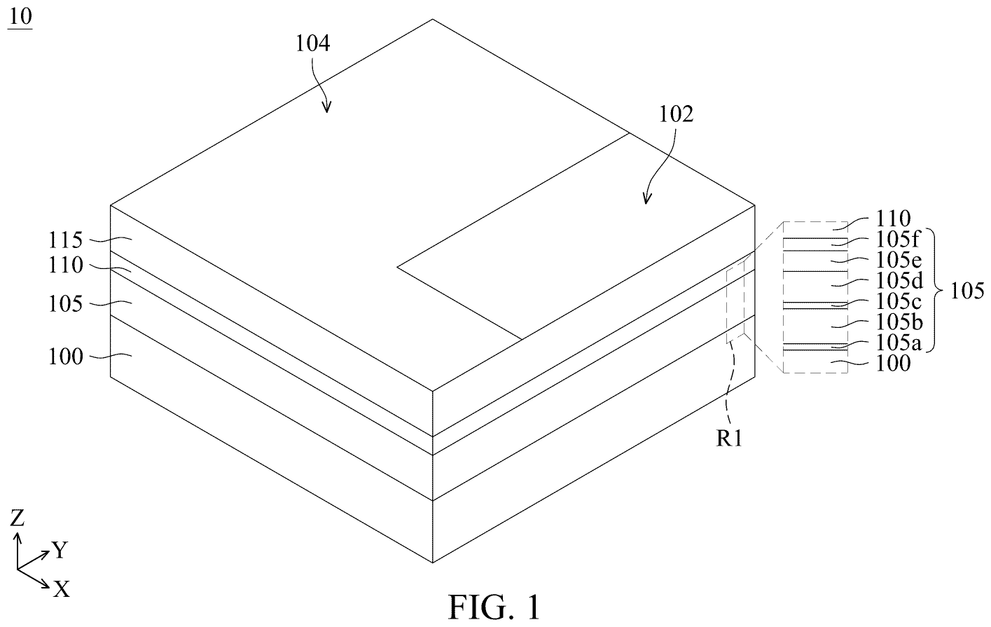

FIG. 1 illustrates a perspective view of an intermediate stage of manufacturing a memory device 10 according to the embodiments of the present disclosure. A substrate 100 is provided. The substrate 100 includes an array region 102 and a peripheral region 104 (it is noted that the array region 102 and the peripheral region 104 are only illustratively shown on the hard mask layer 115 in FIG. 1). The peripheral region 104 of the substrate 100 surrounds the array region 102. The substrate 100 may be an elemental semiconductor substrate, such as a silicon substrate or a germanium substrate; a compound semiconductor substrate, such as silicon carbide (SiC), gallium arsenide (GaAs), indium arsenide (InAs), or indium phosphide (InP) substrate; or an alloy semiconductor substrate, such as SiGe, SiGeC, GaAsP, or GaInP. The substrate 100 may also be a semiconductor-on-insulator (SOI) substrate. The above semiconductor-on-insulator substrate may include a base plate, a buried oxide layer disposed on the base plate, and a semiconductor layer disposed on the above buried oxide layer.

Referring to FIG. 1, a stacked layer 105, a sacrificial layer 110, and a hard mask layer 115 are sequentially formed on the substrate 100. First, the stacked layer 105 is formed on the substrate 100. The stacked layer 105 is film layers stacked in the third direction (e.g., the direction Z of the coordinate axis), and the third direction intersects with the first direction (e.g., the direction Y of the coordinate axis) and the second direction (e.g., the direction X of the coordinate axis). The third direction is perpendicular to the first direction and the second direction. The stacked layer 105, from bottom to top in the third direction, may sequentially include, for example, a tunneling dielectric layer 105a, a floating gate layer 105b, an inter-gate dielectric layer 105c, a control gate layer 105d, a metal layer 105e, and a top cap layer 105f. For simplicity, these layers are only partially illustrated in a region R1 of FIG. 1, and the subsequent views schematically show only the stacked layer 105. The material of the tunneling dielectric layer 105a may be silicon oxide. The material of the floating gate layer 105b may be a conductive material, such as doped polysilicon, undoped polysilicon, or a combination thereof. The inter-gate dielectric layer 105c may be a composite layer, such as oxide/nitride/oxide (ONO), but the present disclosure is not limited thereto. The composite layer may also consist of five or more layers. The material of the control gate layer 105d may be a conductive material, such as doped polysilicon, undoped polysilicon, or a combination thereof. The material of the metal layer 105e may be a material such as tungsten (W), titanium nitride (TiN), or a combination thereof. The material of the top cap layer 105f may be a dielectric material, such as silicon nitride, silicon oxynitride, or a combination thereof.

A sacrificial layer 110 is formed on the stacked layer 105. The sacrificial layer 110 may protect the stacked layer 105 from being affected by the etching process during the subsequent patterning of the hard mask layer 115 (for example, in the step of transferring the connecting pattern, the first pattern, and the second pattern to the hard mask layer 115). The material of the sacrificial layer 110 includes silicon oxide.

Referring to FIG. 1, a hard mask layer 115 is formed on the sacrificial layer 110. The hard mask layer 115 may serve as a patterned mask for the stacked layer 105 in subsequent process steps, the hard mask layer 115 may be a single-layer or multi-layer structure. The material of the hard mask layer 115 includes polycrystalline silicon (poly-Si).

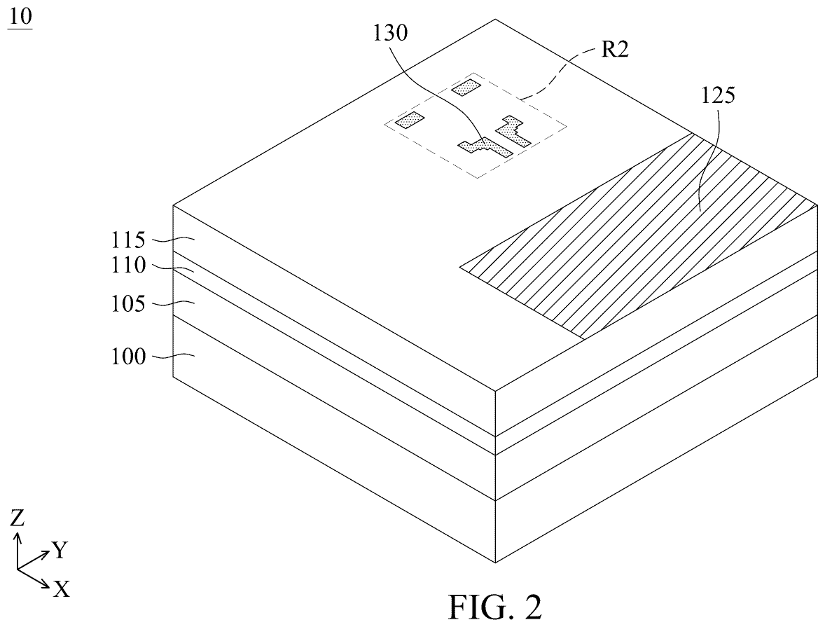

Referring to FIG. 2, FIG. 2 illustrates a perspective view of an intermediate stage of manufacturing the memory device 10 according to the embodiments of the present disclosure. A first patterning process is performed on the substrate 100 to form an array pattern 125 in the array region 102, and the first patterning process also forms a connecting pattern 130 in the peripheral region 104. The first patterning process is a self-aligned double patterning (SADP) process, but it should be understood that the first patterning process may also be a self-aligned quadruple patterning (SAQP) process. Specifically, in the embodiments where the first patterning process is the self-aligned double patterning (SADP) process, a patterned mandrel (not shown) may first be formed on the hard mask layer 115. The patterned mandrel is formed by first forming a mandrel layer (not shown) on the hard mask layer 115, followed by photolithography and etching processes to form a photoresist pattern (not shown) on the mandrel layer.

After forming the photoresist pattern, a trimming process may be performed to further reduce the width of the photoresist pattern, followed by an etching process to transfer the photoresist pattern to the mandrel layer, thereby forming the patterned mandrel. The material of the patterned mandrel may include carbon, silicon oxynitride (SiON), bottom anti-reflective coating (BARC), or a combination thereof.

The self-aligned double patterning (SADP) process is continued to form the array pattern 125 in the array region 102. First, a spacer material layer (not shown) is conformally formed on the hard mask layer 115 and the patterned mandrel. After forming the spacer material layer, the self-aligned double patterning process further includes an etching-back process on the spacer material layer until a top surface of a portion of the hard mask layer 115 is exposed, thereby forming the array pattern 125 in the array region 102. It should be understood that the array pattern 125 is only illustratively shown on the top surface of the hard mask layer 115 and not separately shown. The spacer material layer may be formed by processes such as chemical vapor deposition (CVD), atomic layer deposition (ALD), or a combination thereof. The material of the spacer material layer may be an oxide, such as silicon oxide (SiO).

In the embodiment of the present disclosure, during performing the first patterning process, the array pattern 125 and the connecting pattern 130 are formed simultaneously. In other words, the photomask used in the first patterning process not only includes the pattern corresponding to the array pattern 125 but also includes the pattern corresponding to the connecting pattern 130, thereby forming the connecting pattern 130 in the peripheral region 104 simultaneously while forming the array pattern 125. As mentioned above, in the embodiment of the present disclosure, during performing the first patterning process in the array region 102, the connecting pattern 130 is pre-formed in the peripheral region 104 to replace the overlapping portions of the pattern in subsequent photolithography processes, thereby improving the connectivity issues in the subsequent formation of the peripheral circuit 150 and maintaining the performance of the memory device 10.

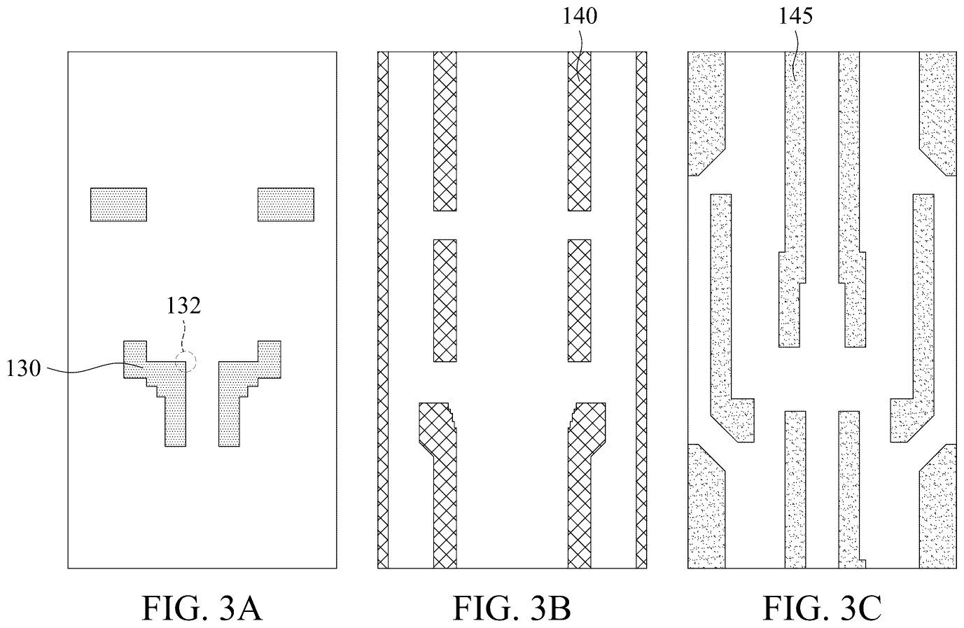

FIGS. 3A, 3B, and 3C illustrate top views of intermediate stages of manufacturing the memory device 10 according to the embodiments of the present disclosure. More specifically, FIGS. 3A, 3B, and 3C illustrate fragmentary top views corresponding to the region R2 of FIG. 2. In some embodiments, FIG. 3A illustrates a fragmentary top view of the connecting pattern 130. FIG. 3B illustrates a fragmentary top view of the first pattern 140. FIG. 3C illustrates a fragmentary top view of the second pattern 145. After forming the array pattern 125 and the connecting pattern 130, a second patterning process is performed on the peripheral region 104 of the substrate 100, sequentially forming a first pattern 140 and a second pattern 145 over the connecting pattern 130. The second patterning process is a lithography-etching-lithography-etching (LELE) process. As mentioned above, in order to respond to the scaling down of the related process, the pattern of the structure of the peripheral circuit may be split into multi-layer patterns, and the complete peripheral circuit may then be formed by etching process. In the embodiment of the present disclosure, the overlapping portions of the original pattern (e.g., for connections) are replaced by the connecting pattern 130, which helps to increase the process margin of subsequent etching processes. Specifically, the connecting pattern 130, the first pattern 140, and the second pattern 145 are mask patterns located in different layers. The first pattern 140 and the second pattern 145 are parallel to each other. The connecting pattern 130 has a corner 132, as shown in FIG. 3A. The angle of the corner 132 is not greater than 90 degrees.

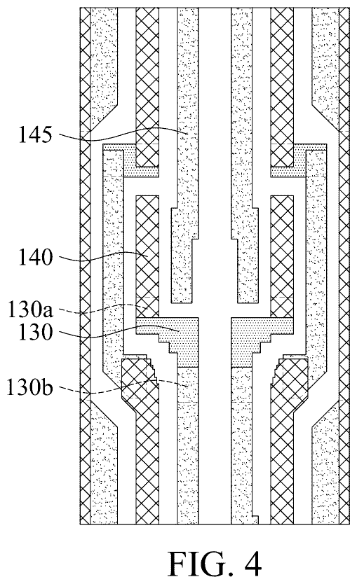

FIG. 4 illustrates a top view of an intermediate stage of manufacturing the memory device 10 according to the embodiments of the present disclosure. More specifically, FIG. 4 illustrates a fragmentary top view corresponding to the region R2 of FIG. 2 after forming the second pattern 145. It should be understood that FIG. 4 only illustratively shows the relative positional relationship of the connecting pattern 130, the first pattern 140, and the second pattern 145 in the top view, and does not indicate a connection relationship to each other. Referring to FIG. 4, one end 130a of the connecting pattern 130 overlaps the first pattern 140, while the other end 130b of the connecting pattern 130 overlaps the second pattern 145. Referring to FIG. 4, the first pattern 140 is connected to the second pattern 145 by the connecting pattern 130. The overlapping area of the connecting pattern 130 with the first pattern 140 is equal to the overlapping area of the connecting pattern 130 with the second pattern 145.

An etching process is performed on the substrate 100 to sequentially transfer the connecting pattern 130, the first pattern 140, and the second pattern 145 to the hard mask layer 115 and the stacked layer 105, thereby forming the peripheral circuit 150 in the peripheral region 104.

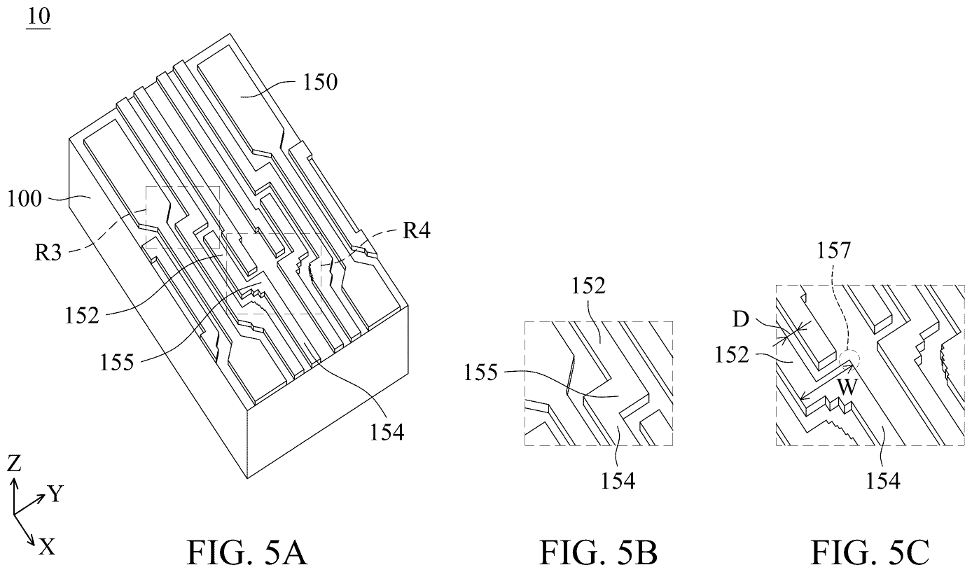

FIGS. 5A, 5B, and 5C illustrate perspective views of intermediate stages of manufacturing the memory device 10 according to the embodiments of the present disclosure. More specifically, FIG. 5A illustrates a perspective view of the region R2 of FIG. 2 after performing the etching process, i.e., illustrating a fragmentary perspective view of the peripheral circuit 150 of the memory device 10. FIGS. 5B and 5C respectively illustrate enlarged perspective views corresponding to the regions R3 and R4 of FIG. 5A. The peripheral circuit 150 is located in the peripheral region 104. The peripheral circuit 150 includes a first portion 152 and a second portion 154, and the first portion 152 and the second portion 154 are electrically connected by a connecting portion 155. The connecting portion 155 approximately corresponds to the connecting pattern 130, the first portion 152 approximately corresponds to the first pattern 140, and the second portion 154 approximately corresponds to the second pattern 145. Referring to FIG. 5C, the connecting portion 155 has a corner 157, the angle of the corner 157 is not greater than 90 degrees. Referring to FIG. 5C, the connecting portion 155 has a width of W in the first direction (e.g., the direction Y of the coordinate axis), and the width W is greater than the distance D between the first portion 152 and the second portion 154 in the first direction. Referring to FIG. 5A, the first portion 152 is arranged in the first direction and extends in the second direction (e.g., the direction X of the coordinate axis), and the second portion 154 is arranged in the first direction and extends in the second direction. The connecting portion 155 may include a rectangle, an L-shape, or a combination thereof. The contact area of the first portion 152 with the connecting portion 155 is equal to the contact area of the second portion 154 with the connecting portion 155.

After forming the peripheral circuit 150, other semiconductor processes may be continued to form various components and elements of the memory device 10, such as forming landing pads and select gates, or performing further implantation processes, which are not described herein.

In summary, the embodiment of the present disclosure effectively solves the structural connectivity issues caused by the stacking of multi-layer patterns and increases the process margin by pre-forming a connecting pattern in the peripheral region during patterning the array region to replace the overlapping portions of the patterns in subsequent photolithography processes, thereby maintaining and improving the performance of the memory device. It should be understood that not all advantages have been necessarily discussed here, and not all embodiments require specific advantages, and other embodiments may offer different advantages.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a memory device, comprising:
providing a substrate with an array region and a peripheral region;
forming a stacked layer on the substrate;
forming a hard mask layer on the stacked layer;
performing a first patterning process on the substrate to form an array pattern in the array region, wherein the first patterning process forms a connecting pattern in the peripheral region;
performing a second patterning process on the peripheral region of the substrate to sequentially form a first pattern and a second pattern over the connecting pattern; and
performing an etching process on the substrate to sequentially transfer the connecting pattern, the first pattern, and the second pattern to the hard mask layer and the stacked layer to form a peripheral circuit in the peripheral region.

2. The method as claimed in claim 1, wherein in a top view, an end of the connecting pattern overlaps the first pattern, and another end of the connecting pattern overlaps the second pattern.

3. The method as claimed in claim 2, wherein in the top view, the first pattern is connected to the second pattern by the connecting pattern.

4. The method as claimed in claim 2, wherein an overlapping area of the connecting pattern and the first pattern is equal to an overlapping area of the connecting pattern and the second pattern.

5. The method as claimed in claim 1, wherein the connecting pattern comprises a corner.

6. The method as claimed in claim 5, wherein an angle of the corner is not greater than 90 degrees.

7. The method as claimed in claim 1, wherein the first pattern and the second pattern are parallel to each other.

8. The method as claimed in claim 1, wherein the first patterning process comprises a self-aligned double patterning (SADP) process.

9. The method as claimed in claim 1, wherein the array pattern and the connecting pattern are formed simultaneously.

10. The method as claimed in claim 1, wherein before forming the hard mask layer on the stacked layer, the method further comprises:
forming a sacrificial layer on the stacked layer, wherein the sacrificial layer protects the stacked layer from etching when transferring the connecting pattern, the first pattern, and the second pattern to the hard mask layer.

11. The method as claimed in claim 10, wherein the hard mask layer comprises polysilicon, and the sacrificial layer comprises silicon oxide.

12. A memory device, comprising:
a substrate with an array region and a peripheral region; and
a peripheral circuit in the peripheral region, wherein the peripheral circuit comprises a first portion and a second portion, wherein the first portion and the second portion are electrically connected by a connecting portion.

13. The memory device as claimed in claim 12, wherein the connecting pattern comprises a corner.

14. The memory device as claimed in claim 13, wherein an angle of the corner is not greater than 90 degrees.

15. The memory device as claimed in claim 12, wherein the connecting portion has a width in a first direction, and the width is greater than a distance between the first portion and the second portion in the first direction.

16. The memory device as claimed in claim 12, wherein the first portion is arranged in a first direction and extends in a second direction, wherein the second portion is arranged in the first direction and extends in the second direction.

17. The memory device as claimed in claim 12, wherein the connecting portion comprises a rectangle, an L-shape, or a combination thereof.

18. The memory device as claimed in claim 12, wherein a contact area of the first portion with the connecting portion is equal to a contact area of the second portion with the connecting portion.

19. The memory device as claimed in claim 12, wherein the first portion and the second portion are parallel to each other.

20. The memory device as claimed in claim 12, wherein the connecting portion is in contact with an end of the first portion.
